(19) United States
(12) Patent Application Publication
(10) Pub. No.: US 2026/0236047 A1
(43) Pub. Date: Aug. 13, 2026

(54) PRESSURE REGULATING SYSTEM AND PRESSURE REGULATING METHOD OF COOLING DEVICE

(71) Applicant: LITE-ON TECHNOLOGY CORPORATION, Taipei (TW)

(72) Inventors: Shih-Kai CHOU, Taipei (TW); Yung-Chang CHIU, Taipei (TW)

(21) Appl. No.: 19/452,457

(22) Filed: Jan. 19, 2026

Related U.S. Application Data
(60) Provisional application No. 63/757,373, filed on Feb. 12, 2025.

(30) Foreign Application Priority Data
Sep. 22, 2025 (TW) 114136319

(51) Int. Cl. G05D 16/20; H05K 7/20

(52) U.S. Cl. CPC G05D 16/2066; H05K 7/20263; H05K 7/20272; H05K 7/20281

(57) ABSTRACT

A pressure regulating system including a pipeline, a heat exchanger, a pump and a hydraulic regulation module is provided. The heat exchanger and the pump are fluidly connected to the outlet and inlet of the pipeline, respectively. The hydraulic regulation module includes a pressure sensor for detecting a pressure value of the cooling liquid between the heat exchanger and the pump, a regulation pipeline fluidly connected to the pipeline at a regulation port located between the heat exchanger and the pump, and a controller. The controller controls a supplementary liquid to flow from the regulation pipeline into the pipeline via the regulation port in response to the pressure value being lower than a target pressure, and controls the cooling liquid to be discharged from the pipeline via the regulation port to the regulation pipeline in response to the pressure value being higher than the target pressure.

This application claims the benefits of US provisional application Serial No. 63/757,373, filed February 12, 2025 and Taiwan application Serial No. 114136319, filed September 22, 2025, the subject matters of which are incorporated herein by reference.

### BACKGROUND OF THE INVENTION

### Field of the Invention

The invention relates in general to a pressure regulating system and a pressure regulating method, and more particularly to a pressure regulating system and a pressure regulating method of a cooling device.

### Description of the Related Art

With the development of technology, the performance of computing devices, such as servers, has become increasingly powerful. However, high-power computing devices generate a large amount of heat, which may significantly affect their performance if not effectively dissipated. Although a cooling system including a pump has been proposed, in which the cooling liquid is continuously delivered to the computing device via the pump for heat dissipation, continuous operation of the pump over a long period may cause bubbles to form in the cooling liquid due to changes in water flow pressure. This may result in cavitation, leading to damage of the pump blades and shortening the pump life. Furthermore, if the bubbles encounter sudden high-pressure impacts, they may implode, generating unstable fluid flow. The bubbles themselves also impede the flow of the cooling liquid, thereby significantly reducing overall cooling efficiency and adversely affecting heat dissipation performance.

### SUMMARY OF THE INVENTION

The present invention relates to a pressure regulating system and a pressure regulating method of a cooling device. By providing a hydraulic regulation module to detect a pressure of the pipeline, the pipeline pressure can be adjusted in real time to maintain a target pressure, thereby avoiding sudden changes in the pipeline pressure and preventing cavitation.

According to an aspect of the present invention, a pressure regulating system of a cooling device is provided. The pressure regulating system includes a pipeline, a heat exchanger, a pump and a hydraulic regulation module. The pipeline allows a cooling liquid to flow therethrough and includes an outlet and an inlet. The cooling liquid returns from a rack to the pipeline via the outlet and is delivered to the rack via the inlet. The heat exchanger is disposed adjacent to the outlet and is fluidly connected to the pipeline. The pump is disposed adjacent to the inlet and is fluidly connected to the pipeline. The hydraulic regulation module includes a pressure sensor, a regulation pipeline and a controller. The pressure sensor is disposed between the heat exchanger and the pump to detect a pressure value of the cooling liquid between the heat exchanger and the pump. The regulation pipeline is fluidly connected to the pipeline at a regulation port, the regulation port being located between the heat exchanger and the pump. The controller is coupled to the pressure sensor to maintain the pressure value at a target pressure. In response to the pressure value being lower than the target pressure, the controller controls a supplementary liquid to flow from the regulation pipeline into the pipeline via the regulation port. In response to the pressure value being higher than the target pressure, the controller controls the cooling liquid to be discharged from the pipeline via the regulation port to the regulation pipeline.

According to another aspect of the present invention, a pressure regulating method of a cooling device is provided. The cooling device includes a pipeline, a heat exchanger and a pump. The heat exchanger and the pump are fluidly connected to the pipeline. The pipeline allows a cooling liquid to flow therethrough and is fluidly connected to a regulation pipeline at a regulation port, the regulation port being located between the heat exchanger and the pump. The pressure regulating method includes the following steps. First, a pressure sensor detects a pressure value of the cooling liquid between the heat exchanger and the pump. Next, a controller maintains the pressure value at a target pressure. In response to the pressure value being lower than the target pressure, the controller controls a supplementary liquid to flow from the regulation pipeline into the pipeline via the regulation port. In response to the pressure value being higher than the target pressure, the controller controls the cooling liquid to be discharged from the pipeline via the regulation port to the regulation pipeline.

The above and other aspects of the invention will become better understood with regard to the following detailed description of the preferred but non-limiting embodiment(s). The following description is made with reference to the accompanying drawings.

### BRIEF DESCRIPTION OF THE DRAWINGS

FIG. 1 illustrates a schematic circulation diagram of a pressure regulating system of a cooling device according to one embodiment of the present invention.

FIG. 2 illustrates a block diagram of the hydraulic regulation module of FIG. 1.

FIG. 3 illustrates a flowchart of a pressure regulating method of a cooling device according to one embodiment of the present invention.

FIG. 4 illustrates a flowchart of a pressure regulating method of a cooling device according to another embodiment of the present invention.

### DETAILED DESCRIPTION OF THE INVENTION

The following describes various embodiments of the present invention with reference to the accompanying drawings. Beyond these detailed descriptions, the present invention may be broadly implemented in other embodiments, and any straightforward substitutions, modifications, or equivalent variations of any of the disclosed embodiments are included within the scope of the present invention, which is defined by the appended claims. In the description of the specification, numerous specific details and exemplary embodiments are provided to give the reader a more complete understanding of the present invention; however, these specific details and exemplary embodiments should not be construed as limiting the invention. Furthermore, well-known steps or elements are not described in detail to avoid imposing unnecessary limitations on the invention. In the drawings, like or similar reference numerals are used to denote like or similar elements.

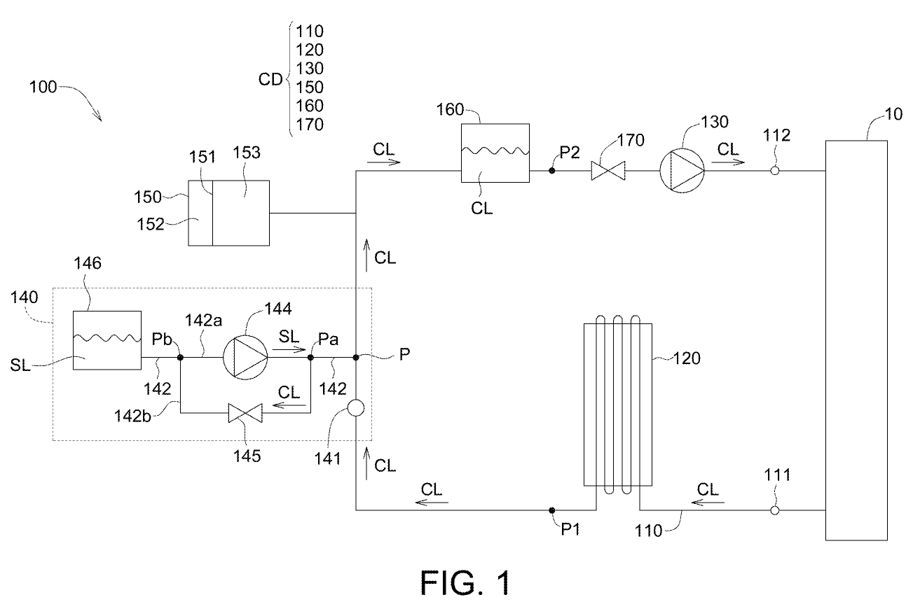

FIG. 1 illustrates a schematic circulation diagram of a pressure regulating system 100 of a cooling device CD according to one embodiment of the present invention. Referring to FIG. 1, the cooling device CD may be used to cool various types of computing devices. The computing device may be installed on a rack 10 and supported by the rack 10. The computing device includes multiple electronic elements that generate heat during operation. The heat generated by the computing device may be dissipated by the cooling device CD. In one embodiment, the computing device or the electronic elements in the computing device may be immersed in a cooling liquid, which carries the heat and then returns to the cooling device CD for temperature reduction. In another embodiment, the computing device or the electronic elements in the computing device may use a gas (e.g., air) as a medium to carry away the heat, which is subsequently dissipated by the cooling device CD.

The cooling device CD at least includes a pipeline 110, a heat exchanger 120 and a pump 130. The pipeline 110 allows a cooling liquid CL to flow therethrough. The cooling liquid CL may be water, but is not limited thereto. The pipeline 110 includes an outlet 111 and an inlet 112. The cooling liquid CL may return from the rack 10 to the pipeline 110 via the outlet 111, and may be delivered to the rack 10 via the inlet 112.

The heat exchanger 120 is disposed adjacent to the outlet 111 of the pipeline 110 and is fluidly connected to the pipeline 110. The cooling liquid CL returning from the rack 10 to the pipeline 110 via the outlet 111 becomes heated as it absorbs heat from the rack 10. When the heated cooling liquid CL passes through the heat exchanger 120, the heat exchanger 120 transfers heat and removes thermal energy from the cooling liquid CL, thereby cooling the cooling liquid CL. As a result, the cooling liquid CL passing through the heat exchanger 120 may have a lower temperature at a position P1 in the pipeline 110. The heat exchanger 120 may be any device capable of dissipating heat during system operation, for example, but not limited to, a radiator, a plate-type heat exchanger, or the like.

The pump 130 is disposed adjacent to the inlet 112 of the pipeline 110 and is fluidly connected to the pipeline 110. After being cooled by the heat exchanger 120, the cooling liquid CL may be delivered to the rack 10 by the pump 130 via the inlet 112, thereby forming a cooling circulation loop.

Referring to FIG. 1, the cooling device CD may further include a reservoir 160 and a valve element 170. The reservoir 160 may be disposed between the heat exchanger 120 and the pump 130 and is fluidly connected to the pipeline 110. The reservoir 160 stores additional cooling liquid CL to serve as a buffer for the pump 130 to draw the cooling liquid CL during operation. The valve element 170 may be arranged between the reservoir 160 and the pump 130 to prevent the cooling liquid CL from flowing back into the reservoir 160 after being pressurized by the pump 130.

In addition, the cooling device CD may further include an expansion tank 150. The expansion tank 150 may be disposed between the heat exchanger 120 and the pump 130 and is fluidly connected to the pipeline 110. Further, the expansion tank 150 may be disposed between the heat exchanger 120 and the reservoir 160. The expansion tank 150 includes a diaphragm 151, which separates a gas chamber 152 and a liquid chamber 153, the liquid chamber 153 being fluidly connected to the pipeline 110. The diaphragm 151 may move in response to pressure changes between the gas chamber 152 and the liquid chamber 153. When the pressures of the gas chamber 152 and the liquid chamber 153 are balanced, the diaphragm 151 stops moving. For example, if the cooling liquid CL in the pipeline 110 expands in volume due to a temperature increase, the expanded cooling liquid CL flows into the liquid chamber 153, increasing the pressure in the liquid chamber 153 and pushing the diaphragm 151 toward the gas chamber 152 until the pressures are balanced. Conversely, if the cooling liquid CL in the pipeline 110 contracts in volume due to a temperature decrease, the gas chamber 152, previously compressed by the diaphragm 151, pushes the diaphragm 151 toward the liquid chamber 153, causing a portion of the cooling liquid CL originally in the liquid chamber 153 to flow back into the pipeline 110 until the pressures are balanced. Accordingly, the expansion tank 150 may maintain stable pressure in the pipeline 110 and prevent sudden pressure fluctuations.

However, the expansion tank 150 may only passively maintain the pressure in the pipeline 110. In particular, once the pressure in the pipeline 110 exceeds the pressure range that the expansion tank 150 can control, for example, if the pressure is too high or too low, the pressure in the pipeline 110 cannot be released in a timely manner. This may result in damage to critical elements of the cooling device CD, such as the pipeline 110 or the pump 130, thereby adversely affecting the heat dissipation performance.

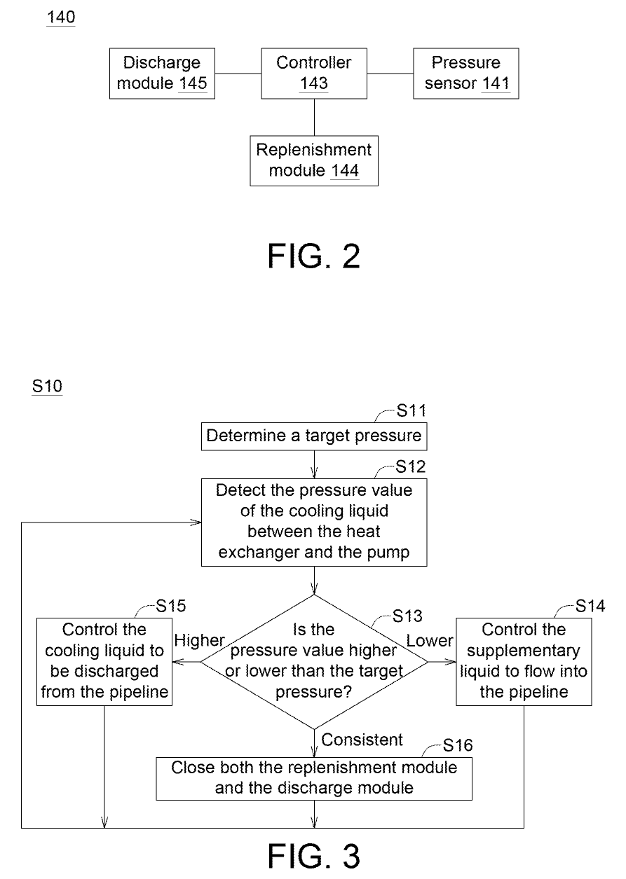

In this regard, the pressure regulating system 100 of the cooling device CD may include a hydraulic regulation module 140. Referring to FIGS. 1 and 2, FIG. 2 illustrates a block diagram of the hydraulic regulation module 140 of FIG. 1. The hydraulic regulation module 140 may include a pressure sensor 141, a regulation pipeline 142 and a controller 143. To prevent hydraulic pressure of the heat exchanger 120 or the pump 130 from affecting the pressure detected in the pipeline 110, the pressure sensor 141 may be disposed between the heat exchanger 120 and the pump 130 to detect the pressure value of the cooling liquid CL between the heat exchanger 120 and the pump 130. Furthermore, the pressure sensor 141 may be disposed at any position between positions P1 and P2 of the pipeline 110, for example, between the heat exchanger 120 and the reservoir 160, to detect the pressure value of the cooling liquid CL between positions P1 and P2.

The regulation pipeline 142 is fluidly connected to the pipeline 110 at a regulation port P, wherein the regulation port P is disposed between the heat exchanger 120 and the pump 130. Furthermore, the regulation port P may be disposed at any position between positions P1 and P2 of the pipeline 110 and may be arranged adjacent to the pressure sensor 141.

The controller 143 is coupled to the pressure sensor 141 to maintain the pressure value of the cooling liquid CL between the heat exchanger 120 and the pump 130 at a target pressure. Furthermore, the controller 143 may maintain the pressure value of the cooling liquid CL at critical positions within the pipeline 110, for example, at any position between positions P1 and P2 of the pipeline 110. When the pressure value between positions P1 and P2 is below the preset target pressure, the controller 143 may control a supplementary liquid SL to flow from the regulation pipeline 142 into the pipeline 110 via the regulation port P to raise the pressure of the cooling liquid CL and prevent potential cavitation. When the pressure value between positions P1 and P2 is above the set target pressure, the controller 143 may control the cooling liquid CL to be discharged from the pipeline 110 via the regulation port P into the regulation pipeline 142 to release the pressure in the pipeline 110 and prevent possible leakage due to overpressure.

Compared to the expansion tank 150, the hydraulic regulation module 140 may actively maintain the pressure in the pipeline 110 to prevent the pressure in the pipeline 110 between the heat exchanger 120 and the pump 130 from becoming too high or too low, thereby avoiding an adverse impact on the heat dissipation performance of the cooling device CD.

Referring to FIGS. 1 and 2, in one embodiment, the hydraulic regulation module 140 may further include a replenishment module 144 and a discharge module 145. The replenishment module 144 and the discharge module 145 may be fluidly connected to the regulation pipeline 142. The controller 143 may be coupled to the replenishment module 144 and the discharge module 145, and may control the replenishment module 144 to flow the supplementary liquid SL toward the regulation port P, and control the discharge module 145 to discharge the cooling liquid CL from the regulation port P.

In one specific embodiment, the replenishment module 144 may be a replenishment pump, and the discharge module 145 may be a solenoid valve. The replenishment module 144 and the discharge module 145 divide the regulation pipeline 142 into two parallel paths between positions Pa and Pb of the regulation pipeline 142. The replenishment module 144 may be fluidly connected to a first path 142a of the regulation pipeline 142, and the discharge module 145 may be fluidly connected to a second path 142b of the regulation pipeline 142, wherein the first path 142a and the second path 142b intersect only at positions Pa and Pb of the regulation pipeline 142. When the replenishment module 144 is activated, it only allows the supplementary liquid SL to flow only in the direction from position Pb toward position Pa. When the discharge module 145 is activated, it allows the cooling liquid CL to flow in the direction from position Pa toward position Pb. In addition, the hydraulic regulation module 140 may further include an external reservoir 146. The external reservoir 146 is fluidly connected to the regulation pipeline 142 and is disposed at the end of the regulation pipeline 142. The external reservoir 146 may store the supplementary liquid SL and may receive the cooling liquid CL flowing from the regulation pipeline 142.

FIG. 3 illustrates a flowchart of a pressure regulating method S10 of a cooling device CD according to one embodiment of the present invention. Referring to FIGS. 1, 2 and 3, first, in step S11, a target pressure may be determined.

Next, in step S12, the pressure sensor 141 detects the pressure value of the cooling liquid CL between the heat exchanger 120 and the pump 130, and this pressure value is then transmitted to the controller 143. Then, in step S13, the controller 143 compares the detected pressure value with the target pressure.

When the controller 143 determines that the pressure value is lower than the target pressure, as in step S14, the controller 143 activates the replenishment module 144 and closes the discharge module 145, thereby allowing the supplementary liquid SL to flow into the pipeline 110.

When the controller 143 determines that the pressure value is higher than the target pressure, as in step S15, the controller 143 activates the discharge module 145 and closes the replenishment module 144, thereby allowing the cooling liquid CL to be discharged from the pipeline 110.

When the pressure value is determined to be consistent with the target pressure, as in step S16, the controller 143 closes both the replenishment module 144 and the discharge module 145. That is, no supplementary liquid SL flows into the pipeline 110 through the regulation port P, and no cooling liquid CL is discharged from the pipeline 110 through the regulation port P.

As shown in FIG. 3, the controller 143 continuously monitors the detected pressure value relative to the target pressure, and close both the replenishment module 144 and the discharge module 145 only when the pressure value matches the target pressure.

In one embodiment, the target pressure determined in step S11 may be within a pressure interval. A range of the pressure interval may be determined according to the replenishment speed of the replenishment module 144 and/or the discharge speed of the discharge module 145, such that when the pressure value of the cooling liquid CL deviates from the target pressure, the replenishment module 144 and/or the discharge module 145 may gradually restore the pressure value to the target pressure within a predetermined time. This prevents the replenishment module 144 and/or the discharge module 145 from being damaged due to frequent opening and closing.

In one embodiment, the pressure value of the cooling liquid CL may vary in response to the temperature of the cooling liquid CL. For example, if the operating power of the computing device increases, causing the cooling liquid CL to heat up due to absorbing excessive heat from the rack 10, the overall volume of the cooling liquid CL will expand, resulting in a pressure value higher than the target pressure. In this case, the controller 143 executes step S15 until the pressure value matches the target pressure, and then step S16 is executed. Conversely, when the operating power of the computing device decreases, causing the temperature of the cooling liquid CL to drop, the overall volume of the cooling liquid CL will shrink, resulting in a pressure value lower than the target pressure. In this case, the controller 143 executes step S14 until the pressure value matches the target pressure, and then step S16 is executed.

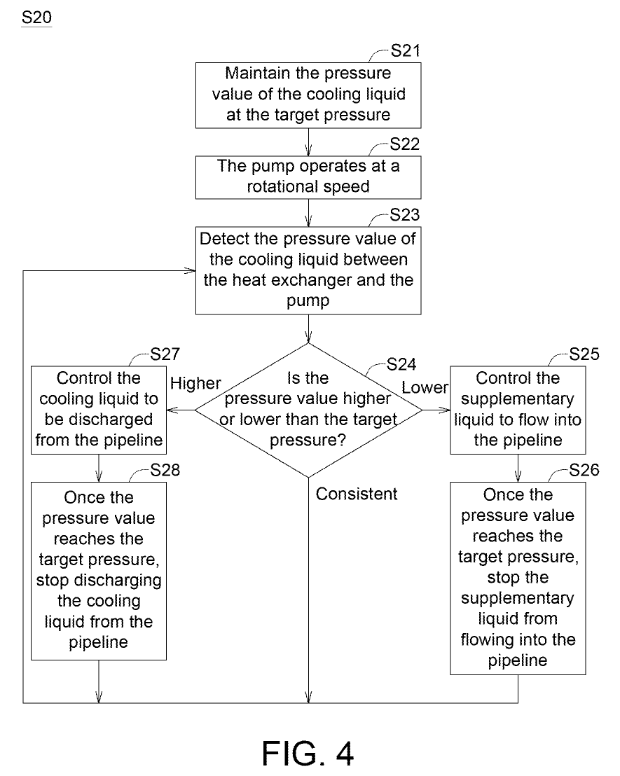

FIG. 4 illustrates a flowchart of a pressure regulating method S20 of a cooling device CD according to another embodiment of the present invention. Referring to FIGS. 1, 2, 3, and 4, in one embodiment, the pressure value of the cooling liquid CL may vary in response to the rotational speed of the pump 130. Therefore, the target pressure determined in step S11 may be set to be not lower than a saturated vapor pressure of the cooling liquid CL at a maximum operating temperature based on the pump 130 operating at a maximum rotational speed and the cooling liquid CL being at the maximum operating temperature, thereby preventing the generation of cavitation.

In step S21, the pressure value of the cooling liquid CL is maintained at the target pressure as described above. Then, in step S22, the pump 130 operates at a rotational speed. The rotational speed of the pump 130 may be adjusted based on the monitored temperatures at the outlet 111 and inlet 112. For example, if the temperatures at the outlet 111 and inlet 112 rise, the rotational speed of the pump 130 may be increased to more quickly deliver the cooling liquid CL to the rack 10; if the temperatures at the outlet 111 and inlet 112 decrease, the rotational speed of the pump 130 may be appropriately reduced. Next, in step S23, the pressure sensor 141 detects the pressure value of the cooling liquid CL between the heat exchanger 120 and the pump 130, and the detected pressure value is transmitted to the controller 143. Then, in step S24, the controller 143 compares the pressure value with the target pressure.

In one scenario, if the lower pressure in the pipeline 110 is caused by a low-pressure region generated by the high rotational speed of the pump 130, then when the pressure is determined to be below the target pressure, as in step S25, the controller 143 actives the replenishment module 144 and closes the discharge module 145, so that the supplementary liquid SL flows into the pipeline 110. In step S26, the controller 143 continuously monitors the pressure value relative to the target pressure. Once the pressure value reaches the target pressure, the controller 143 controls the replenishment module 144 to close, so as to stop the supplementary liquid SL from flowing into the pipeline 110.

In another scenario, if the rotational speed of the pump 130 is relatively low, causing the controller 143 in step S24 to determine that the pressure value is higher than the target pressure, then in step S27, the controller 143 controls the discharge module 145 to open and the replenishment module 144 to close, so that the cooling liquid CL is discharged from the pipeline 110. In step S28, the controller 143 continuously monitors the pressure value relative to the target pressure. Once the pressure value reaches the target pressure, the controller 143 controls the discharge module 145 to close, so as to stop discharging the cooling liquid CL from the pipeline 110.

In step S24, if the controller 143 determines that the pressure value matches the target pressure, the discharge module 145 does not operate. In this way, the pump 130 may operate at an optimal rotational speed without causing significant changes in the pressure of the pipeline 110.

In summary, a pressure regulating system and a pressure regulating method of a cooling device provided by the present invention may actively maintain the pressure within the pipeline and adjust the target pressure as needed, which cannot be achieved by a conventional expansion tank. At the same time, the present invention may timely adjust the pressure in the pipeline based on changes in the temperature of the cooling liquid and the rotational speed of the pump, thereby preventing cavitation caused by excessively low pressure and avoiding potential leakage due to overpressure.

While the invention has been described by way of example and in terms of the preferred embodiment(s), it is to be understood that the invention is not limited thereto. Based on the technical features embodiments of the present invention, a person ordinarily skilled in the art will be able to make various modifications and similar arrangements and procedures without breaching the spirit and scope of protection of the invention. Therefore, the scope of protection of the present invention should be accorded with what is defined in the appended claims.

What is claimed is:

1. A pressure regulating system of a cooling device comprising:
a pipeline through which a cooling liquid flows, the pipeline having an outlet and an inlet, the cooling liquid returning from a rack to the pipeline via the outlet and being delivered to the rack via the inlet;
a heat exchanger disposed adjacent to the outlet and fluidly connected to the pipeline;
a pump disposed adjacent to the inlet and fluidly connected to the pipeline; and
a hydraulic regulation module comprising:
a pressure sensor disposed between the heat exchanger and the pump and configured to detect a pressure value of the cooling liquid between the heat exchanger and the pump;
a regulation pipeline fluidly connected to the pipeline at a regulation port, the regulation port being located between the heat exchanger and the pump; and
a controller coupled to the pressure sensor and configured to maintain the pressure value at a target pressure;
wherein in response to the pressure value being lower than the target pressure, the controller controls a supplementary liquid to flow into the pipeline from the regulation pipeline via the regulation port; and
in response to the pressure value being higher than the target pressure, the controller controls the cooling liquid to be discharged from the pipeline to the regulation pipeline via the regulation port.

2. The pressure regulating system according to claim 1, wherein the regulation port is disposed adjacent to the pressure sensor.

3. The pressure regulating system according to claim 1, wherein the target pressure is within a pressure interval.

4. The pressure regulating system according to claim 1, wherein the hydraulic regulation module further comprises a replenishment module and a discharge module, the replenishment module and the discharge module are fluidly connected to the regulation pipeline, the replenishment module is configured to cause the supplementary liquid to flow toward the regulation port, the discharge module is configured to discharge the cooling liquid from the regulation port, and the controller is coupled to and controlling the replenishment module and the discharge module.

5. The pressure regulating system according to claim 4, wherein in response to the pressure value being lower than the target pressure, the controller controls the replenishment module to open and the discharge module to close; and in response to the pressure value being higher than the target pressure, the controller controls the discharge module to open and the replenishment module to close.

6. The pressure regulating system according to claim 4, wherein in response to the pressure value being maintained at the target pressure, the controller controls the replenishment module and the discharge module to close.

7. The pressure regulating system according to claim 4, wherein the target pressure is within a pressure interval, a range of the pressure interval being determined according to a replenishment speed of the replenishment module and a discharge speed of the discharge module, such that in response to the pressure value of the cooling liquid deviating from the target pressure, the replenishment module or the discharge module restores the pressure value to the target pressure within a predetermined time.

8. The pressure regulating system according to claim 4, wherein the hydraulic regulation module further comprises an external reservoir fluidly connected to the regulation pipeline.

9. The pressure regulating system according to claim 1, further comprising:
a reservoir disposed between the heat exchanger and the pump and fluidly connected to the pipeline.

10. The pressure regulating system according to claim 1, further comprising:
an expansion tank disposed between the heat exchanger and the pump and fluidly connected to the pipeline.

11. The pressure regulating system according to claim 1, wherein the target pressure is set to be not lower than a saturated vapor pressure of the cooling liquid at a maximum operating temperature based on the pump operating at a maximum rotational speed and the cooling liquid being at the maximum operating temperature.

12. The pressure regulating system according to claim 1, wherein the controller is further configured to:
in response to the pressure value being lower than the target pressure while the pump operates at a certain rotational speed, control the supplementary liquid to flow into the pipeline; and
in response to the pressure value being adjusted to the target pressure, stop the supplementary liquid from flowing into the pipeline.

13. The pressure regulating system according to claim 1, wherein the controller is further configured to:
in response to the pressure value being higher than the target pressure while the pump operates at a certain rotational speed, control the cooling liquid to be discharged from the pipeline; and
in response to the pressure value being adjusted to the target pressure, stop discharging the cooling liquid from the pipeline.

14. The pressure regulating system according to claim 1, wherein the pressure value of the cooling liquid varies in response to a temperature of the cooling liquid.

15. A pressure regulating method of a cooling device comprising:
detecting, by a pressure sensor, a pressure value of a cooling liquid between a heat exchanger and a pump of the cooling device, the cooling device further comprising a pipeline through which the cooling liquid flows, the pipeline being fluidly connected to the heat exchanger and the pump, and the pipeline being fluidly connected to a regulation pipeline at a regulation port, the regulation port being located between the heat exchanger and the pump; and
maintaining, by a controller, the pressure value at a target pressure;
wherein in response to the pressure value being lower than the target pressure, the controller controls a supplementary liquid to flow from the regulation pipeline into the pipeline via the regulation port; and
in response to the pressure value being higher than the target pressure, the controller controls the cooling liquid to be discharged from the pipeline via the regulation port to the regulation pipeline.

16. The pressure regulating method according to claim 15, wherein the regulation pipeline is further fluidly connected to a replenishment module and a discharge module;
in response to the pressure value being lower than the target pressure, the controller controls the replenishment module to cause the supplementary liquid to flow toward the regulation port and closes the discharge module; and
in response to the pressure value being higher than the target pressure, the controller controls the discharge module to cause the cooling liquid to be discharged from the regulation port and closes the replenishment module.

17. The pressure regulating method according to claim 16, wherein in response to the pressure value being maintained at the target pressure, the controller controls the replenishment module and the discharge module to close.

18. The pressure regulating method according to claim 16, wherein the target pressure is defined as a pressure interval, a range of the pressure interval is determined according to a replenishment speed of the replenishment module and a discharge speed of the discharge module, such that in response to the pressure value of the cooling liquid deviating from the target pressure, the replenishment module or the discharge module restores the pressure value to the target pressure within a predetermined time.

19. The pressure regulating method according to claim 15, wherein the target pressure is set to be not lower than a saturated vapor pressure of the cooling liquid at a maximum operating temperature based on the pump operating at a maximum rotational speed and the cooling liquid being at the maximum operating temperature.

20. The pressure regulating method according to claim 15, wherein the pressure value of the cooling liquid varies in response to a rotational speed of the pump and/or a temperature of the cooling liquid.
